(19) United States
(12) Patent Application Publication
(10) Pub. No.: US 2013/0062701 A1
(43) Pub. Date: Mar. 14, 2013

(54) SEMICONDUCTOR DEVICE AND MANUFACTURING METHOD THEREOF

(71) Applicants: Chiu-Te Lee, Hsinchu City (TW); Chun-Mao Chiou, Chiayi County (TW); You-Di Jhang, New Taipei City (TW)

(72) Inventors: Chiu-Te Lee, Hsinchu City (TW); Chun-Mao Chiou, Chiayi County (TW); You-Di Jhang, New Taipei City (TW)

(21) Appl. No.: 13/227,487

(22) Filed: Sep. 8, 2011

(51) Int. Cl. H01L 27/092; H01L 21/768; H01L 29/78; H01L 21/28

(52) U.S. Cl. 257/369; 438/586; 257/288; 257/E21.585; 257/E21.177; 257/E27.062; 257/E29.255

(57) ABSTRACT

A manufacturing method of a semiconductor device includes the following steps. First, a substrate is provided. At least one sacrificial gate structure is formed on the substrate, at least one diffusion region is formed in the substrate at each of two sides of the sacrificial gate structure, and a first inter-layer dielectric layer is formed to cover the diffusion region. A gate recess is then formed in the sacrificial gate structure. A first diffusion contact hole is then formed in the first inter-layer dielectric layer and at least partially exposes the diffusion region. A metal layer is subsequently formed in the gate recess and the first diffusion contact hole.

### BACKGROUND OF THE INVENTION

1. Field of the Invention

The present invention relates to a semiconductor device and a manufacturing method thereof, and more particularly, to a semiconductor device and a manufacturing method thereof forming a contact hole on a diffusion region before forming a metal gate structure.

2. Description of the Prior Art

Poly-silicon is conventionally used as a gate electrode in semiconductor devices, such as the metal-oxide-semiconductor (MOS). With the trend towards scaling down the size of semiconductor devices, however, conventional poly-silicon gates face problems such as inferior performance due to boron penetration and unavoidable depletion effect. This increases equivalent thickness of the gate dielectric layer, reduces gate capacitance, and worsens a driving force of the devices. Therefore, work function metals that are suitable for use as the high dielectric constant (high-k) gate dielectric layer are used to replace the conventional poly-silicon gate as the control electrode.

In a complementary metal-oxide semiconductor (CMOS) device, one of the dual work function metal gate structures is used in an NMOS device and the other one is used in a PMOS device. It is well known that compatibility and process control for the dual metal gate structure is more complicated, while thickness and composition controls for materials used in the dual metal gate structure method are more precise. The conventional dual metal gate structure methods are categorized into gate first processes and gate last processes. In a conventional dual metal gate structure method applied with the gate first process, both the anneal process for forming the source/drain ultra-shallow junction and the silicide process are performed after forming the metal gate structure. After performing the anneal process with a strict heat budget, it is found that a flat band voltage (Vfb) does not increase or decrease linearly with decreasing EOT of the high-k gate dielectric layer; instead, a roll-off issue is observed. The gate last process is developed to improve the Vfb roll-off issue and avoid generating leakage current due to re-crystallization of the high-k gate dielectric layer occurring in high-temperature processes, and to widen material choices for the high-k gate dielectric layer and the metal gate structure in the gate first process.

In the conventional gate last process, a sacrificial gate or a replacement gate is provided, followed by performing processes used to construct a normal MOS transistor. Then, the sacrificial/replacement gate is removed to form a gate recess. Metals are filled into the gate recess depending upon electrical needs. For example, a work function metal layer, a barrier layer and a main electrode layer are formed in the gate recess. Generally the process described above is regarded as a replacement metal gate (RMG) process. In the conventional process, an etching process is performed for forming a contact plug on a diffusion region after the RMG process. An inter-layer dielectric with a substantial thickness over the diffusion region has to be penetrated by the contact plug, and it becomes more difficult to control the etching process.

### SUMMARY OF THE INVENTION

It is one of the objectives of the present invention to provide a semiconductor device and a manufacturing method thereof The contact hole on the diffusion region is formed before forming the metal gate structure for improving the manufacturing process of the semiconductor device and enhancing the properties of the semiconductor device.

According to a preferred embodiment of the present invention, a manufacturing method of a semiconductor device includes the following steps. First, a substrate is provided. At least a sacrificial gate structure is formed on the substrate, at least one diffusion region is formed in the substrate at each of two sides of the sacrificial gate structure, and a first inter-layer dielectric (ILD) layer is formed to cover the diffusion region. A gate recess is then formed in the sacrificial gate structure. A first diffusion contact hole is then formed in the first inter-layer dielectric layer and at least partially exposes the diffusion region. A metal layer is subsequently formed in the gate recess and the first diffusion contact hole.

According to another preferred embodiment of the present invention, a manufacturing method of a semiconductor device includes the following steps. First, a substrate is provided. At least a first semiconductor unit, at least a second semiconductor unit, and a first ILD layer are formed on the substrate. The first semiconductor unit has a first sacrificial gate structure formed therein and at least a first diffusion region formed in the substrate at two sides of the first sacrificial gate structure, the second semiconductor unit has a second sacrificial gate structure formed therein and at least a second diffusion region formed in the substrate at two sides of the second sacrificial gate structure, and the first ILD layer is formed for covering the first diffusion region and the second diffusion region. A first gate recess is then formed in the first sacrificial gate structure, and a second gate recess is then formed in the second sacrificial gate structure. A plurality of first diffusion contact holes are formed in the first ILD layer for at least partially exposing the first diffusion region or the second diffusion region. A metal layer is subsequently formed in the first gate recess, the second gate recess, and the first diffusion contact hole.

According to a preferred embodiment of the present invention, a semiconductor device includes a substrate, a high-k gate dielectric layer, a metal gate structure, a diffusion region, a first ILD layer, and a diffusion contact plug. The high-k gate dielectric layer is disposed on the substrate. The metal gate structure is disposed on the high-k gate dielectric layer. The diffusion region is disposed in the substrate at two sides of the metal gate structure. The first ILD layer is disposed on the diffusion region, and the first ILD layer has a first diffusion contact hole at least partially exposing the diffusion region. The diffusion contact plug is disposed in the first diffusion contact hole. Both the diffusion contact plug and the metal gate structure comprise a work function layer and a main conductive layer.

According to another preferred embodiment of the present invention, a semiconductor device includes a substrate, a first semiconductor unit, a second semiconductor unit, a first ILD layer, and a plurality of diffusion contact plugs. The first semiconductor unit and a second semiconductor unit are disposed on the substrate. The first semiconductor unit comprises a first metal gate structure and at least a first diffusion region disposed in the substrate at two sides of the first gate structure, and the second semiconductor unit comprises a second metal gate structure and at least a second diffusion region disposed in the substrate at two sides of the second metal gate structure. The first ILD layer is disposed on the first diffusion region and the second diffusion region, and the first ILD layer has a plurality of first diffusion contact holes at least partially exposing the first diffusion region or the second diffusion region. The diffusion contact plugs are respectively disposed in each of the first diffusion contact holes. The diffusion contact plugs, the first metal gate structure and the second metal gate structure comprise a first work function layer and a main conductive layer.

In the present invention, the metal gate structure may avoid being damaged during forming the contact holes because the replacement metal gate process is completed after forming the contact holes. The process window of the etching process for forming the contact hole may accordingly improved, and the process yield and the device quality may also be enhanced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams illustrating a manufacturing method of the semiconductor device according to the first preferred embodiment of the present invention.

FIGS. 3-7 are schematic diagrams illustrating a manufacturing method of the semiconductor device according to the second preferred embodiment of the present invention.

FIGS. 8-12 are schematic diagrams illustrating a manufacturing method of the semiconductor device according to the third preferred embodiment of the present invention.

FIGS. 13-16 are schematic diagrams illustrating a manufacturing method of the semiconductor device according to the fourth preferred embodiment of the present invention.

### DETAILED DESCRIPTION

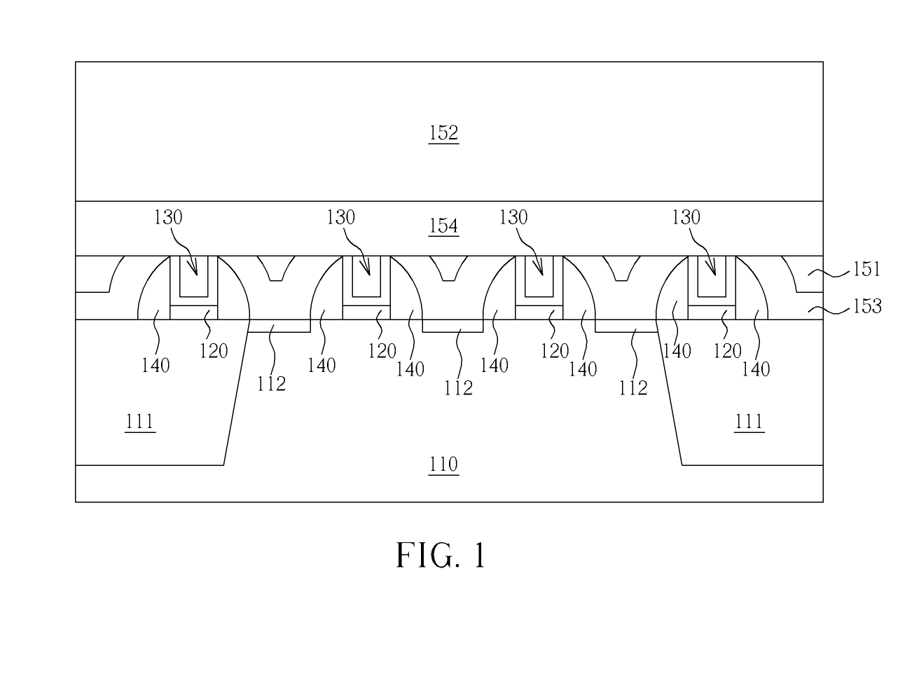

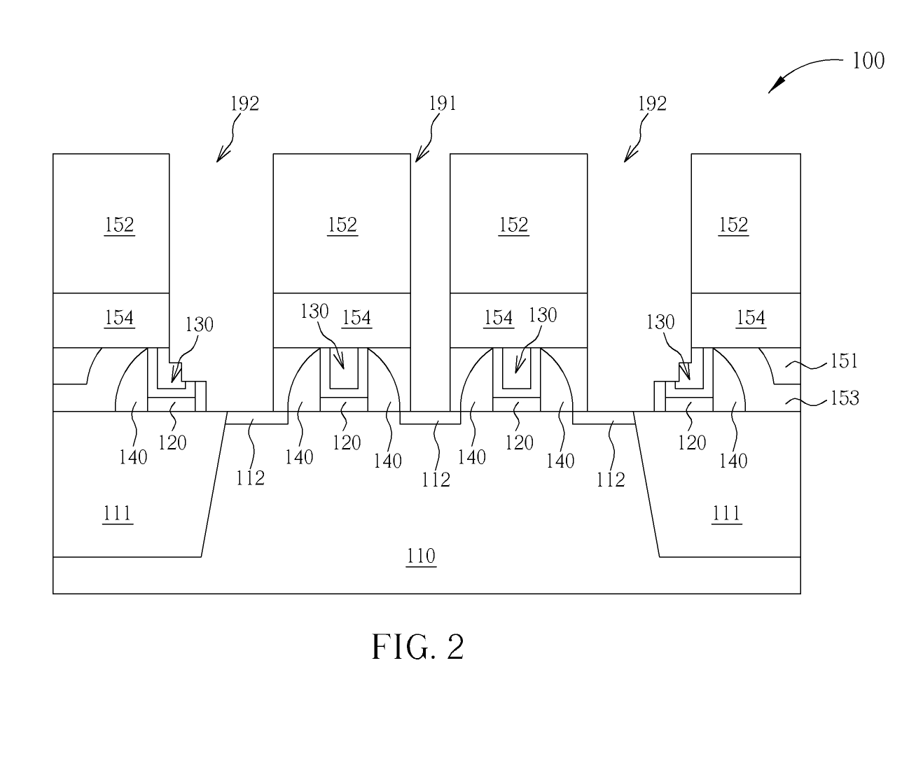

Please refer to FIG. 1 and FIG. 2. FIG. 1 and FIG. 2 are schematic diagrams illustrating a manufacturing method of the semiconductor device according to the first preferred embodiment of the present invention. Please note that the figures are only for illustration and the figures may not be to scale. The scale may be further modified according to different design considerations. The manufacturing method of the semiconductor device in this embodiment includes the following steps. First, as shown in FIG. 1, a substrate 110 is provided. A plurality of metal gate structures 130 are formed on the substrate 110. A plurality of diffusion regions 112, which may be used as source/drain electrodes, are formed in the substrate 110 at each of two sides of the metal gate structure 130 respectively. A plurality of spacers 140 are formed at each of the two sides of the metal gate structure 130 respectively. A plurality of gate dielectric layers 120 are disposed respectively between the substrate 110 and the metal gate structures 130. A first inter-layer dielectric (ILD) layer 151 is formed for covering the diffusion regions 112, and a second ILD layer 152 is formed for covering the metal gate structures 130 and the diffusion regions 112. Additionally, in this embodiment, a plurality of shallow trench isolations (STI) 111 may be formed in the substrate 110 for providing electrical isolation effect, a contact etch stop layer (CESL) 153 may be formed between the first ILD layer 151 and the diffusion regions 112, a nitrogen doped carbide (NDC) layer 153 may be formed between the second ILD layer 152 and the metal gate structures 130, and a metal silicide layer (not shown) may be formed over each of the diffusion regions 112, but the present invention is not limited to this.

As shown in FIG. 2, a diffusion contact hole 191 and a diffusion contact hole 192 may be formed by a photo-etch process for forming a semiconductor device 100. The diffusion contact hole 191 at least partially exposes the diffusion region 112, and the diffusion contact hole 192 at least partially exposes the diffusion region 112 and metal gate structure 130. A conductive material (not shown) may be subsequently formed for filling into the diffusion contact hole 191 and the diffusion contact hole 192. The metal gate structure 130 and the diffusion region 112 exposed by the diffusion contact hole 192 may be electrically connected to each other by the conductive material in the diffusion contact hole 192. The semiconductor device 100 in this embodiment may be employed for forming an SRAM, but not limited thereto. It is worth noticing that the etching selectivity and the over-etch condition have to be controlled carefully for avoiding the metal gate structure 130 being damaged during the etching process which is employed to remove a part of the second ILD layer 152, a part of the NDC layer 154, and a part of the CESL 153 over the diffusion region 112 for forming the diffusion contact hole 192.

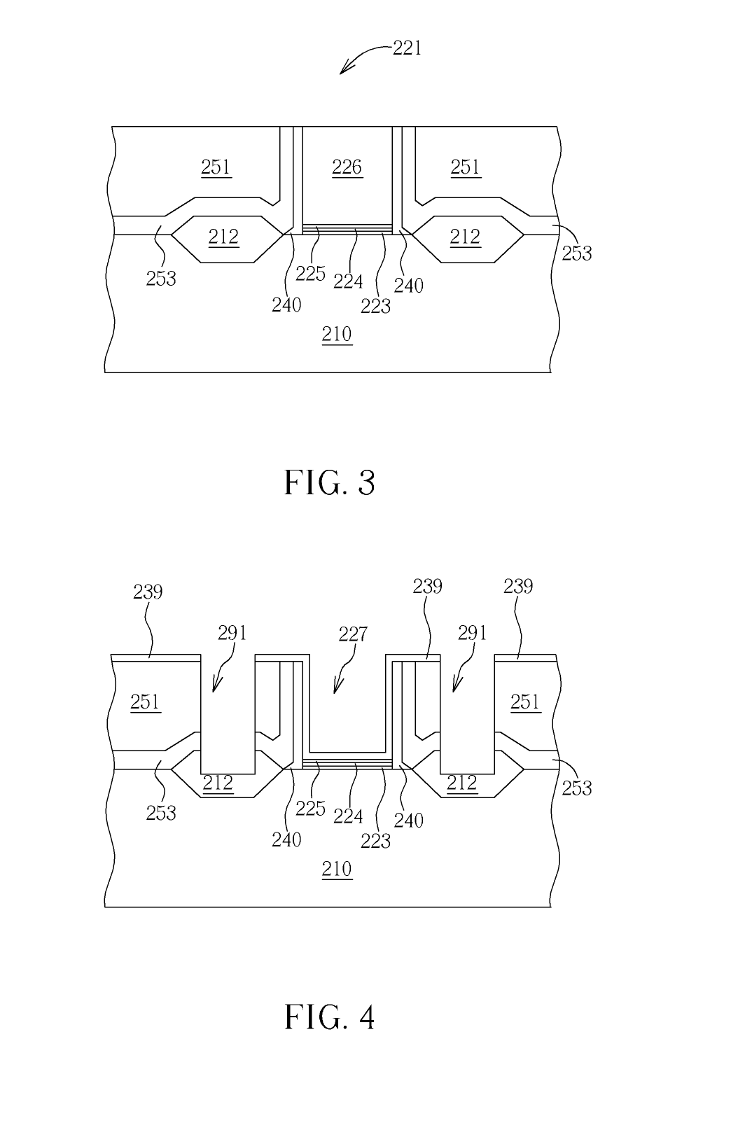

Please refer to FIGS. 3-7. FIGS. 3-7 are schematic diagrams illustrating a manufacturing method of the semiconductor device according to the second preferred embodiment of the present invention. The manufacturing method of the semiconductor device in this embodiment includes the following steps. First, as shown in FIG. 3, a substrate 210 is provided. A sacrificial gate structure 221 is formed on the substrate 210, a diffusion region 212 is formed in the substrate 210 at each of two sides of the sacrificial gate structure 221, and a first ILD layer 251 is formed to cover the diffusion region 212. In this embodiment, the sacrificial gate structure 221 may include a high dielectric constant (high-k) gate dielectric layer 224 and a sacrificial gate material layer 226 such as poly-silicon material layer. The high-k gate dielectric layer 224 may be formed between the substrate 210 and the sacrificial gate material layer 226. Additionally, in this embodiment, a spacer 240 may be formed on two sides of the sacrificial gate structure 221, a CESL 253 may be formed between the first ILD layer 251 and the diffusion region 212, a barrier layer 225 may be formed between the sacrificial gate material layer 226 and the high-k gate dielectric layer 224, and a buffer layer 223 may be formed between the substrate 210 and the high-k gate dielectric layer 224, but the present invention is not limited to this. As shown in FIG. 4, the sacrificial gate material layer 226 may then be removed for forming a gate recess 227 in the sacrificial gate structure 221. A first diffusion contact hole 291 may be formed in the first ILD layer 251 and the CESL 253 by a photo-etch process for at least partially exposing the diffusion region 212. It is worth noticing that a barrier layer 239 may be selectively formed in the gate recess 227 before forming the first diffusion contact hole 291, but not limited thereto.

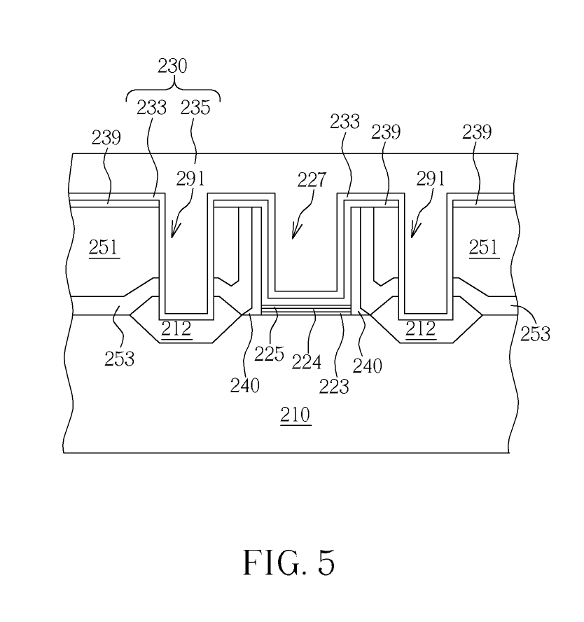

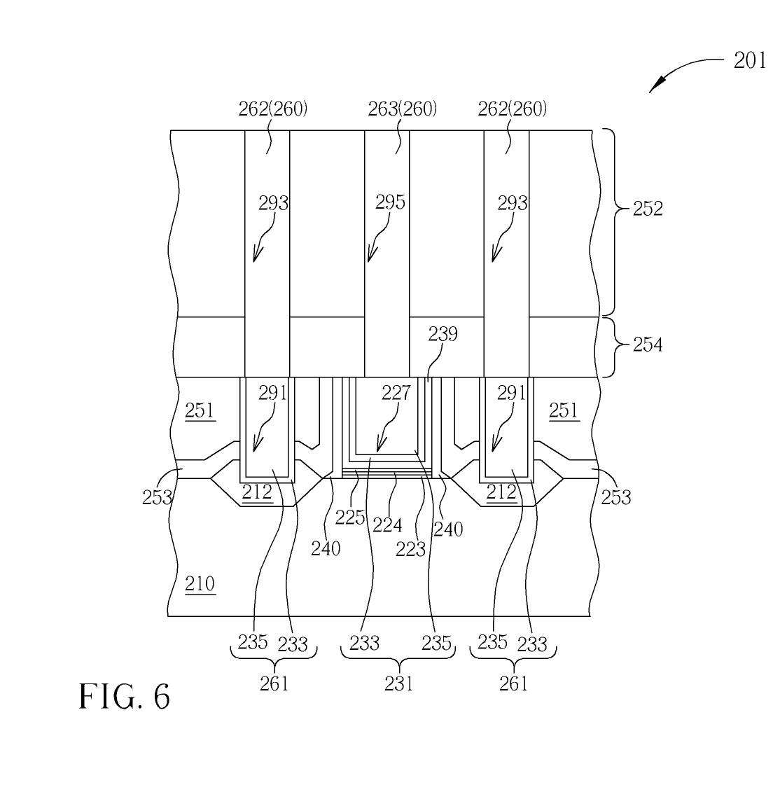

As shown in FIG. 5, a metal layer 230 is then formed at least in the gate recess 227 and the first diffusion contact hole 291, and the metal layer 230 in the gate recess 227 and the first diffusion contact hole 291 may be formed by a same film-forming process simultaneously, but not limited thereto. In this embodiment, the metal layer 230 may include a work function metal layer 233 and a main conductive layer 235. In other words, components of the work function metal layer 233 in the gate recess 227 may be preferably identical to components of the work function metal layer 233 in the first diffusion contact hole 291, and components of the main conductive layer 235 in the gate recess 227 may be preferably identical to components of the main conductive layer 235 in the first diffusion contact hole 291, but the present invention is not limited to this and the components of the main conductive layer 235 in the gate recess 227 may be different from the components of the main conductive layer 235 in the first diffusion contact hole 291, and the components of the work function metal layer 233 in the gate recess 227 may be different from the components of the work function metal layer 233 in the first diffusion contact hole 291. As shown in FIG. 6, a portion of the main conductive layer 235 and the work function metal layer 233 may be then removed by a planarization process, such as a chemical mechanical polishing (CMP) process, for separating the main conductive layer 235 and the work function metal layer 233 in the gate recess 227 from the main conductive layer 235 and the work function metal layer 233 in each of the first diffusion contact holes 291, and forming the metal gate structure 231 and the diffusion contact plug 261 respectively. A second ILD layer 252 may then be formed for covering the substrate 210 and the main conductive layer 235, i.e. the second ILD layer 252 may be formed for covering the metal gate structure 231 and the diffusion contact plug 261. Additionally, in this embodiment, an NDC layer 254 may be selectively formed before forming the second ILD layer 252, but not limited thereto. A gate contact hole 295 and a second diffusion contact hole 293 may then be formed in the second ILD layer 252 and the NDC layer 254. The gate contact hole 295 at least partially exposes the main conductive layer 235 in the gate recess 227, and the second diffusion contact hole 293 at least partially exposes the main conductive layer 235 in the first diffusion contact hole 291. In addition, the manufacturing method of the semiconductor device in this embodiment may further include filling the gate contact hole 295 and the second diffusion contact hole 293 with a conductive material 260, such as aluminum (Al), tungsten (W), copper (Cu), Ti (titanium), titanium nitride (TiN), tantalum (Ta), tantalum nitride (TaN), titanium aluminide (TiAl), and titanium aluminum oxide (TiAlO), but not limited thereto. The conductive material 260 is then partially removed by a planarization process for forming a second diffusion contact plug 262 and a gate contact plug 263. By performing the manufacturing method described above, a semiconductor device 201 shown in FIG. 6 may be obtained. In other words, both the metal gate structure 231 and the diffusion contact plug 261 in the semiconductor device 201 include the work function metal layer 233 and the main conductive layer 235. A process such as an etching process for forming the first diffusion contact hole 291 may not damage the metal gate structure 231 because the metal gate structure 231 is formed after forming the first diffusion contact hole 291. Additionally, in the semiconductor device 201, the second ILD layer 252 is disposed over the metal gate structure 231 and the diffusion contact plug 261, and it is easier to control an etching process for forming the gate contact hole 295 and the second diffusion contact hole 293 simultaneously because the layers which have to be removed over the metal gate structure 231 and over the diffusion contact plug 261 are identical and the widths and depths of the gate contact hole 295 and the second diffusion contact hole 293 are similar too. The gate contact plug 263 and the second diffusion contact plugs 262 are formed in the second ILD layer 252. The gate contact plug 263 is electrically connected to the metal gate structure 231 and each of the second diffusion contact plugs 262 is electrically connected to the diffusion contact plug 261.

In this embodiment, the substrate 210 may be a semiconductor substrate such as a silicon substrate, a silicon containing substrate or a silicon-on-insulator (SOI) substrate. The high-k gate dielectric layer 224 may be selected from a group such as hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO4), strontium bismuth tantalite (SrBi₂Ta₂O₉, SBT), lead zirconate titanate (PbZrₓTi₁₋ₓO₃, PZT) and barium strontium titanate (BaₓSr₁₋ₓTiO₃, BST). The work function metal layer 233 may include an intrinsic work function, and the work function metal layer 233 may be a p-type work function metal layer, an n-type work function metal layer, or a composite layer including both the p-type work function layer and the n-type work function layer for optimizing the work function of the metal gate structure 231. For example, the work function of NMOS is generally between 3.9 eV and 4.3 eV, and the work function of PMOS is generally between 4.8 eV and 5.2 eV, but not limited thereto. The work function metal layer 233 may include titanium nitride (TiN), titanium carbide (TiC), tantalum nitride (TaN), tantalum carbide (TaC), tungsten carbide (WC), titanium tri-aluminide (TiAl3) or aluminum titanium nitride (TiAlN), but not limited thereto. In addition, the work function metal layer 223 may be a single-layered structure or a multi-layered structure. The first ILD layer 251 and the second ILD layer 252 may be a silicon oxide layer or a silicon nitride layer. The spacer 240 may be a single layer structure or a multilayer structure formed by materials such as silicon nitride or silicon oxide. The barrier layer 225 may be employed for protecting the high-k gate dielectric layer 224 during the process of removing the sacrificial gate material layer 226. The barrier layer 225 may include titanium, titanium nitride, tantalum, or tantalum nitride. The main conductive layer 235 may include a conductive material such as aluminum (Al), tungsten (W), copper (Cu), titanium aluminide (TiAl), and titanium aluminum oxide (TiAlO), but not limited thereto. In addition, the diffusion region 212 may include an epitaxial layer such as a silicon germanium epitaxial layer or a silicon carbide epitaxial layer, and a metal silicide (not shown) may be further formed on the diffusion region 212 for improving the contact performance.

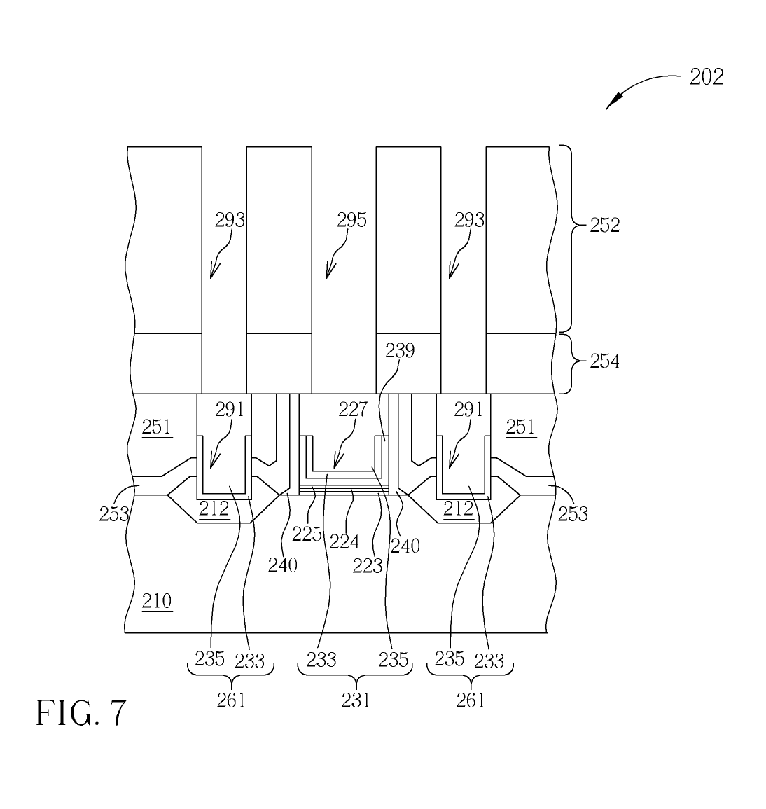

As shown in FIG. 7, a manufacturing method of the semiconductor device according to an exemplary embodiment of the present invention may further include performing an etching process for removing a part of the work function metal layer 233 in the gate recess 227 and the first diffusion contact hole 291 before forming the main conductive layer 235. A part of a side wall of the gate recess 226 and a part of a side wall of the first diffusion contact hole 291 may be exposed for improving a filling condition of the main conductive layer 235 formed subsequently. For example, the manufacturing method described above may include partially filling a sacrificial material (not shown) in the gate recess 227 and the first diffusion contact hole 291 first, and subsequently performing an etching process for removing a part of the work function metal layer 233 uncovered by the sacrificial material in the gate recess 227 and the first diffusion contact hole 291. The sacrificial material mentioned above may include a non-sensitive material, which may be photoresist material, dielectric anti-reflection coating (DARC), light absorbing oxide (DUO) or spin-on glass (SOG). In other words, in the semiconductor device 202 of this exemplary embodiment, the work function metal layer 233 in the gate recess 227 and the first diffusion contact hole 291 may be lower than the main conductive layer 235 in the gate recess 227 and the first diffusion contact hole 291.

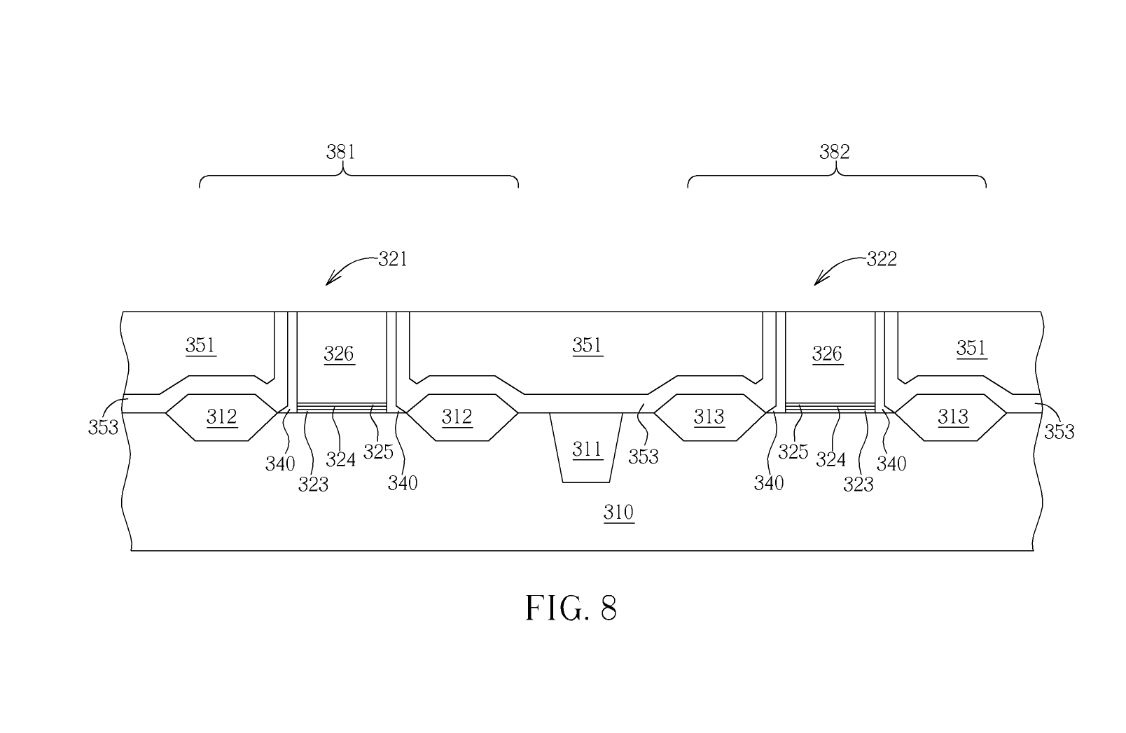

Please refer to FIGS. 8-12. FIGS. 8-12 are schematic diagrams illustrating a manufacturing method of the semiconductor device according to the third preferred embodiment of the present invention. The manufacturing method of the semiconductor device in this embodiment includes the following steps. First, as shown in FIG. 8, a substrate 310 is provided. A first semiconductor unit 381, a second semiconductor unit 382, and a first ILD layer 351 are formed on the substrate 310. A STI 311 may be formed in the substrate 310 between the first semiconductor unit 381 and the second semiconductor unit 382. A first sacrificial gate structure 321 is formed in the first semiconductor unit 381, and two first diffusion regions 312 are formed in the substrate 310 at two sides of the first sacrificial gate structure 321. A second sacrificial gate structure 322 is formed in the second semiconductor unit 382, and two second diffusion regions 313 are formed in the substrate 310 at two sides of the second sacrificial gate structure 322. The first ILD layer 351 is formed for covering the first diffusion region 312 and the second diffusion region 322. In this embodiment, the first sacrificial gate structure 321 and the second sacrificial gate structure 322 may include a high-k gate dielectric layer 324 and a sacrificial gate material layer 326. The high-k gate dielectric layer 324 may be formed between the substrate 310 and the sacrificial gate material layer 326. Additionally, in this embodiment, a spacer 340 may be formed on two sides of the first sacrificial gate structure 321 and the second sacrificial gate structure 322, a CESL 353 may be formed between the first ILD layer 351 and the first diffusion region 312/the second diffusion region 313, a barrier layer 325 may be formed between the sacrificial gate material layer 326 and the high-k gate dielectric layer 324, and a buffer layer 323 may be formed between the substrate 310 and the high-k gate dielectric layer 324, but the present invention is not limited to this. In this embodiment, a conductive type of the first semiconductor unit 381 may be an n-type and a conductive type of the second semiconductor unit 382 may be a p-type, but not limited thereto.

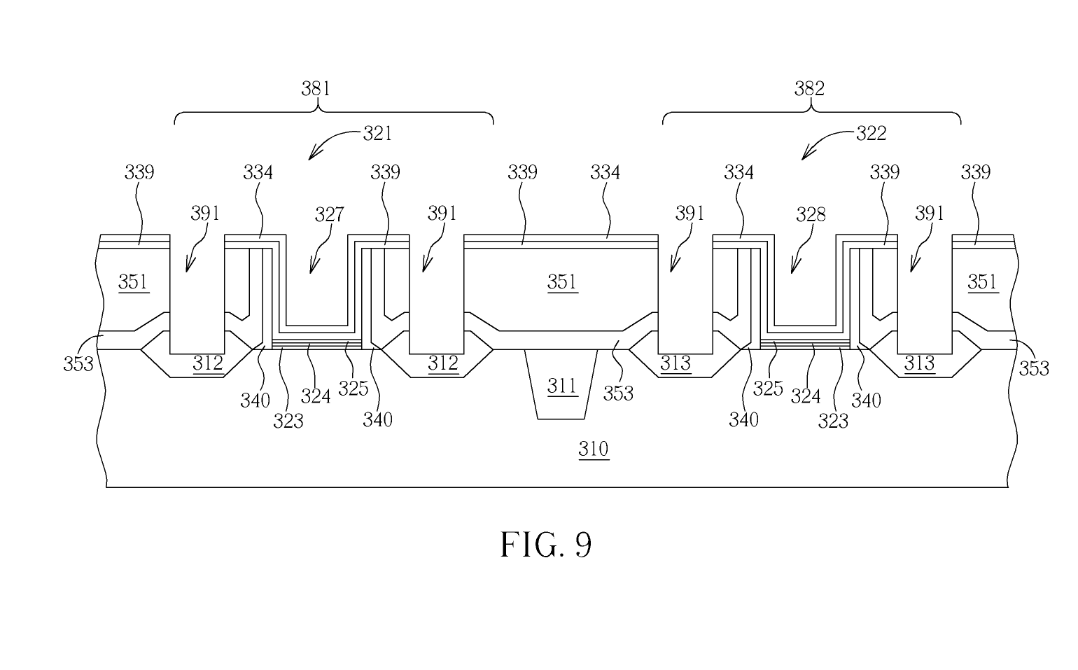

As shown in FIG. 9, the sacrificial gate material layer 326 is then removed for forming a first gate recess 327 and a second gate recess 328 in the first sacrificial gate structure 321 and the second sacrificial gate structure 322 respectively. A plurality of first diffusion contact holes 391 may be formed in the first ILD layer 351 and the CESL 353 by a photo-etch process for at least partially exposing the first diffusion region 312 and the second diffusion region 313. It is worth noticing that a barrier layer 339 and a second work function metal layer 334 may be formed in the first gate recess 327 and the second gate recess 328 before forming the first diffusion contact hole 391, but the present invention is not limited to this.

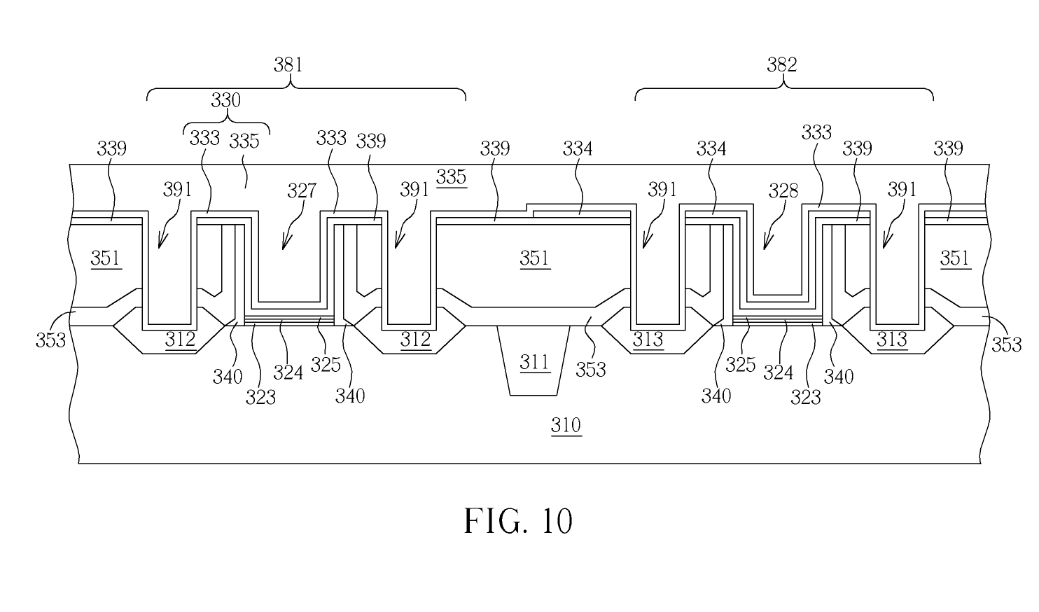

As shown in FIG. 10, the second work function metal layer 334 in the first gate recess 327 may be removed after forming the first diffusion contact hole 391. Subsequently, a metal layer 330 may be formed in the first gate recess 327, the second gate recess 328 and the first diffusion contact holes 391. The metal layer 330 in the first gate recess 327, the second gate recess 328 and the first diffusion contact holes 391 may be formed by a same film-forming process simultaneously, but not limited thereto. In this embodiment, the metal layer 330 may include a first work function metal layer 333 and a main conductive layer 335. In other words, components of the first work function metal layer 333 in the first gate recess 327 and the second gate recess 328 may be preferably identical to components of the first work function metal layer 333 in the first diffusion contact holes 391, and components of the main conductive layer 335 in the first gate recess 327 and the second gate recess 328 may be preferably identical to components of the main conductive layer 335 in the first diffusion contact holes 391, but the present invention is not limited to this and the components of the main conductive layer 335 in the first gate recess 327 and the second gate recess 328 may be different from the components of the main conductive layer 335 in the first diffusion contact holes 391, and the components of the first work function metal layer 333 in the first gate recess 327 and the second gate recess 328 may be different from the components of the first work function metal layer 333 in the first diffusion contact holes 391.

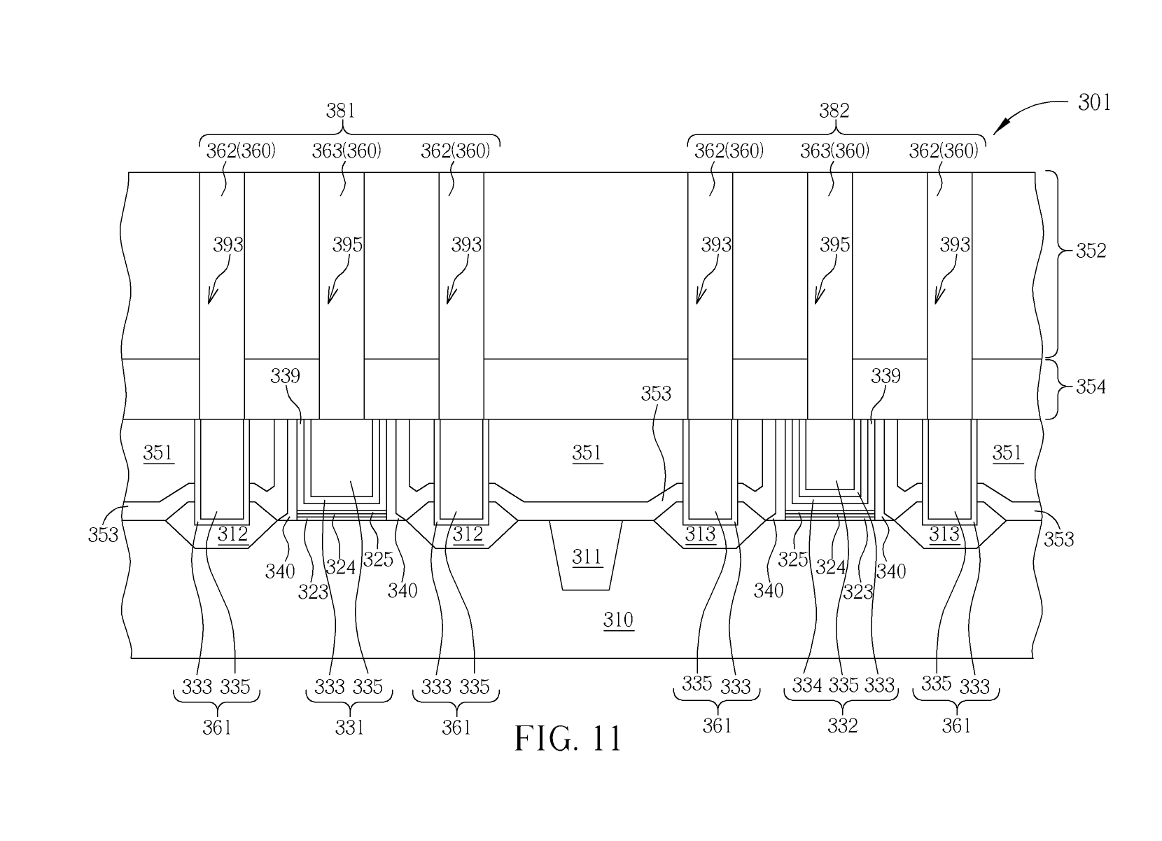

As shown in FIG. 11, a part of the main conductive layer 335, a part of the first work function metal layer 333, and a part of the second work function metal layer 334 may be then removed by a planarization process, such as a chemical mechanical polishing process, for separating the main conductive layer 335, the first work function metal layer 333, and the second work function metal layer 334 in the first gate recess 327, in the second gate recess 328 and in each of the first diffusion contact holes 391, and forming the first metal gate structure 331, the second metal gate structure 332, and the diffusion contact plug 361 respectively. A second ILD layer 352 may then be formed for covering the substrate 310 and the main conductive layer 335, i.e. the second ILD layer 352 may be formed for covering the first metal gate structure 331, the second metal gate structure 332, and the diffusion contact plug 361. Additionally, in this embodiment, an NDC layer 354 may be selectively formed before forming the second ILD layer 352, but not limited thereto. A gate contact hole 395 and a second diffusion contact hole 393 may then be formed in the second ILD layer 352 and the NDC layer 354. The gate contact hole 395 at least partially exposes the main conductive layer 335 in the first gate recess 327 or in the second gate recess 328, and the second diffusion contact hole 393 at least partially exposes the main conductive layer 335 in the first diffusion contact holes 391. In addition, the manufacturing method of the semiconductor device in this embodiment may further include filling the gate contact hole 395 and the second diffusion contact hole 393 with a conductive material 360. The conductive material 360 is then partially removed by a planarization process for forming a second diffusion contact plug 362 and a gate contact plug 363. By performing the manufacturing method described above, a semiconductor device 301 shown in FIG. 11 may be obtained. The material properties of the components in this embodiment are similar to the second preferred embodiment mentioned above and will not be redundantly described. It is worth noticing that the components of the first work function metal layer 333 and the second work function metal layer 334 may be further modified according to different conductivity types of the first semiconductor unit 381 and the second semiconductor unit 382.

Additionally, in the semiconductor device 301 of this embodiment, the first metal gate structure 331, the second metal gate structure 332, and the diffusion contact plug 361 all include the first work function metal layer 333 and the main conductive layer 335. The second metal gate structure 332 may further include the second work function metal layer 334 disposed between the first work function metal layer 333 and the substrate 310. A process such as an etching process for forming the first diffusion contact hole 391 may not damage the first metal gate structure 331 and the second metal gate structure 332 because the first metal gate structure 331 and the second metal gate structure 332 are formed after forming the first diffusion contact holes 391. Additionally, in the semiconductor device 301, the second ILD layer 352 is disposed over the first metal gate structure 331, the second metal gate structure 332 and the diffusion contact plug 361, and it is easier to control an etching process for forming the gate contact hole 395 and the second diffusion contact hole 393 simultaneously because the layers which have to be removed over the first metal gate structure 331, over the second metal gate structure 332, and over the diffusion contact plug 361 are identical and the widths and depths of the gate contact hole 395 and the second diffusion contact hole 393 are similar too. The gate contact plugs 363 and the second diffusion contact plugs 362 are formed in the second ILD layer 352. Each of the gate contact plugs 363 is electrically connected to the first metal gate structure 331 or the second metal gate structure 332, and each of the second diffusion contact plugs 362 is electrically connected to the diffusion contact plug 361. It is worth noticing that the conductive type of the first semiconductor unit 381 may be an n-type and the conductive type of the second semiconductor unit 382 may be a p-type, and the semiconductor device 301 in this embodiment may be employed for forming a CMOS, but not limited thereto.

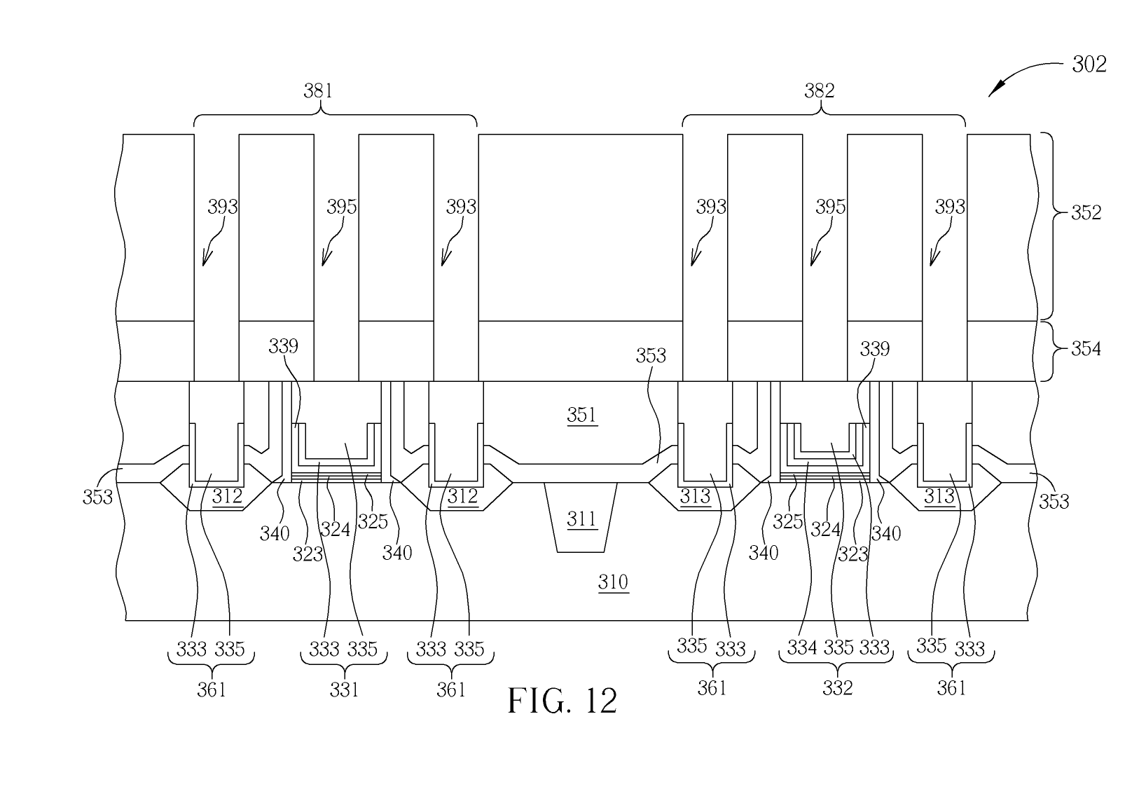

As shown in FIG. 12, a manufacturing method of the semiconductor device according to an exemplary embodiment of the present invention may further include performing an etching process for removing a part of the first work function metal layer 333 and a part of the second work function layer 334 in the first gate recess 327, the second gate recess 328, and the first diffusion contact hole 391 before forming the main conductive layer 335. The details of the process steps are similar to the second preferred embodiment and will not be redundantly described. In other words, in the semiconductor device 302 of this exemplary embodiment, the first work function metal layer 333 and the second work function layer 334 may be lower than the main conductive layer 335.

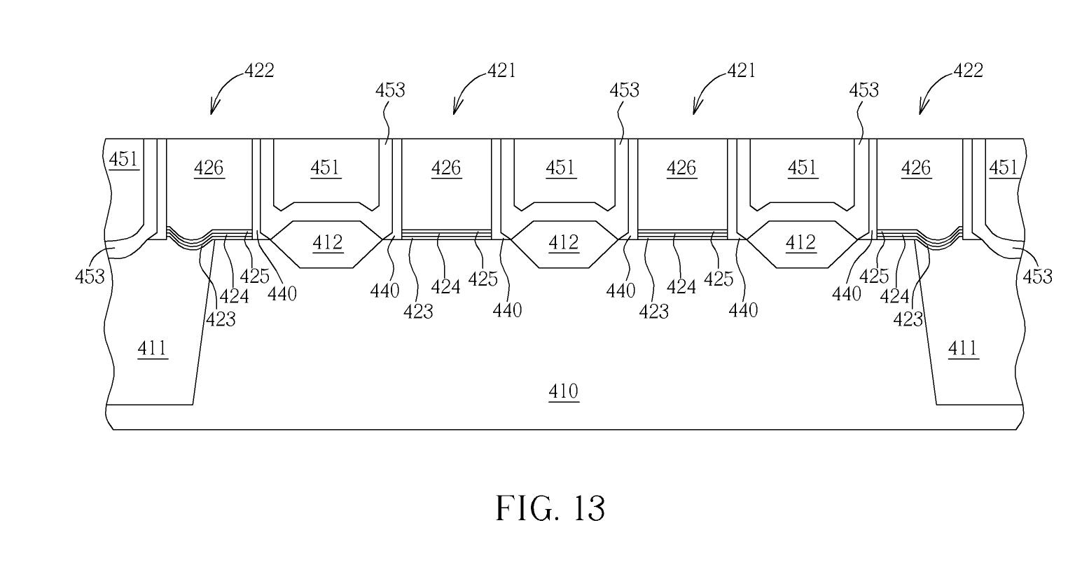

Please refer to FIGS. 13-16. FIGS. 13-16 are schematic diagrams illustrating a manufacturing method of the semiconductor device according to the fourth preferred embodiment of the present invention. The manufacturing method of the semiconductor device in this embodiment includes the following steps. First, as shown in FIG. 13, a substrate 410 is provided. A plurality of first sacrificial gate structures 421, a plurality of second sacrificial gate structures 422, and a first ILD layer 451 are formed on the substrate 410. A plurality of diffusion regions 412 are formed in the substrate 410 at two sides of the first sacrificial gate structures 421 and the second sacrificial gate structures 422. An STI 411 may be formed in the substrate 410, and the second sacrificial gate structure 422 may partially formed on the STI 411, but not limited thereto. The first ILD layer 451 is formed for covering the diffusion regions 412. In this embodiment, the first sacrificial gate structures 421 and the second sacrificial gate structures 422 may include a high-k gate dielectric layer 424 and a sacrificial gate material layer 426. Additionally, in this embodiment, spacers 440 may be formed on two sides of the first sacrificial gate structures 421 and the second sacrificial gate structures 422, a CESL 453 may be formed between the first ILD layer 451 and the diffusion regions 412, a barrier layer 425 may be formed between the sacrificial gate material layer 426 and the high-k gate dielectric layer 424, and a buffer layer 423 may be formed between the substrate 410 and the high-k gate dielectric layer 424, but the present invention is not limited to this.

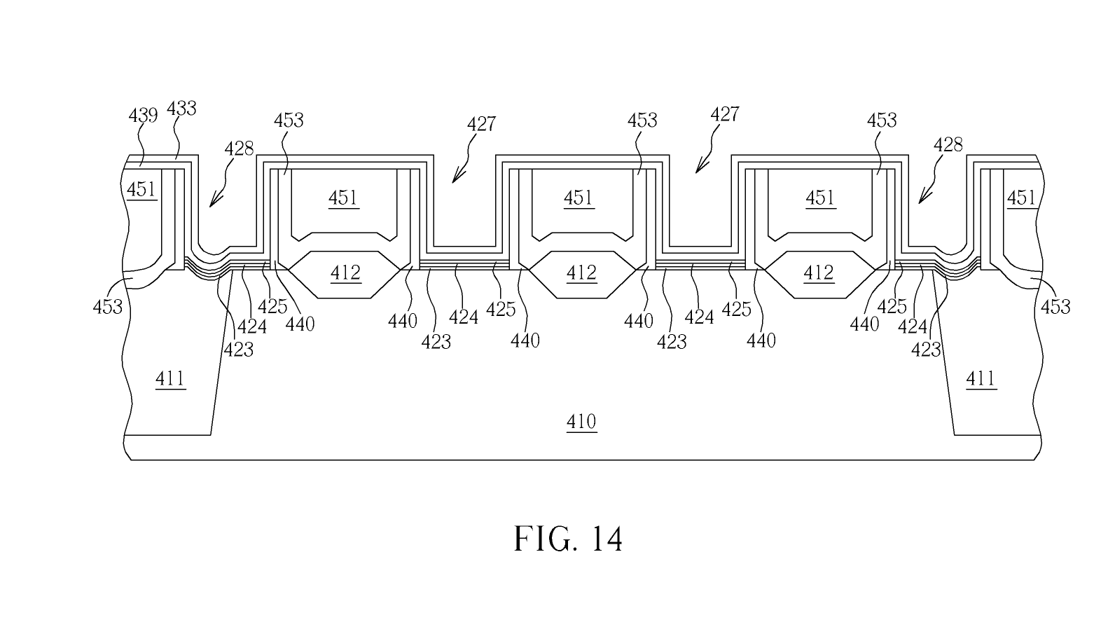

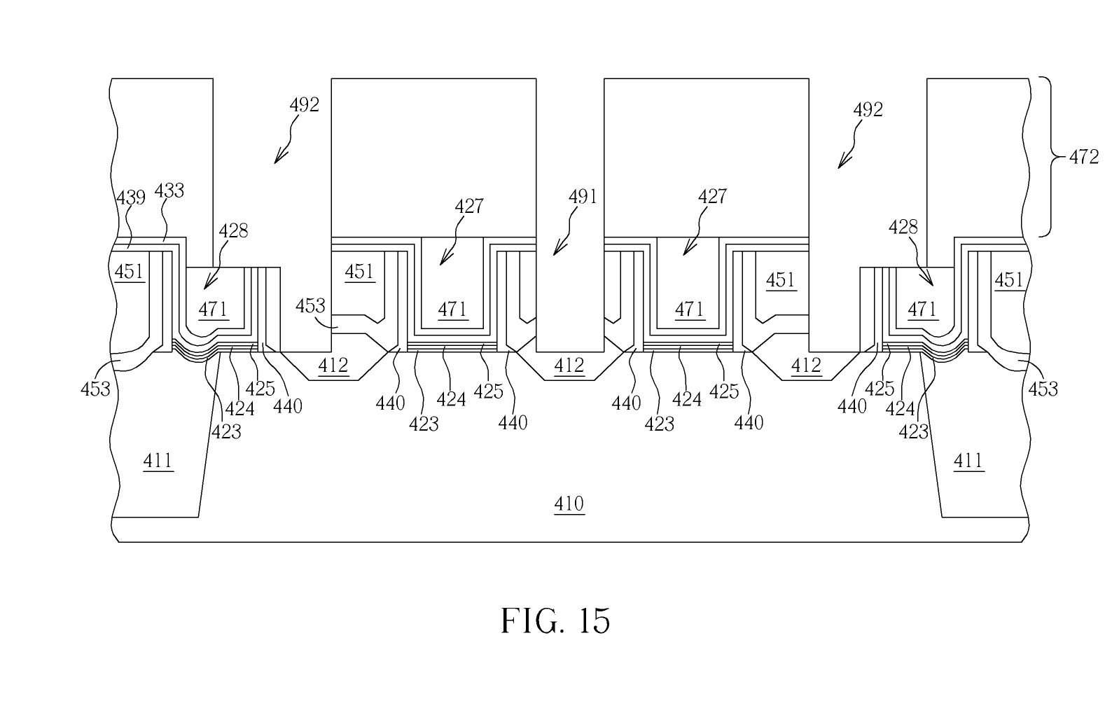

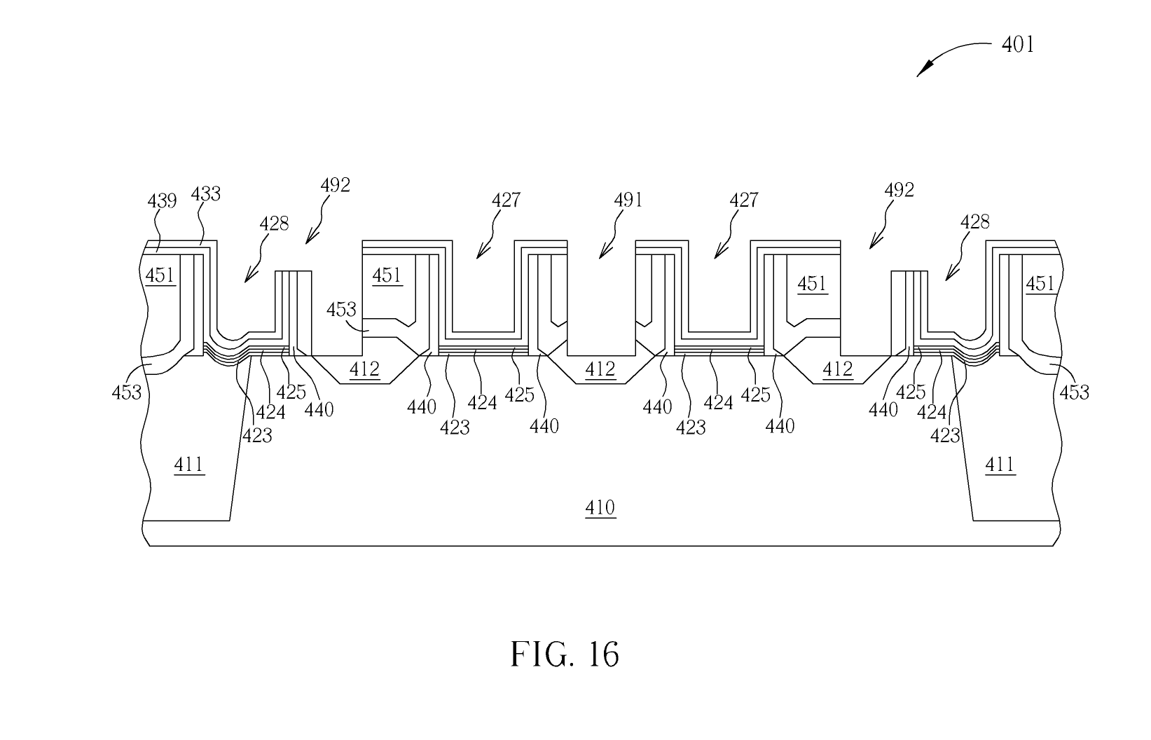

As shown in FIG. 14, a first gate recess 427 and a second gate recess 428 may be formed respectively in each of the first sacrificial gate structures 421 and each of the second sacrificial gate structure 422. A barrier layer 439 and a work function metal layer 433 may be orderly formed in the first gate recess 427 and the second gate recess 428. As shown in FIG. 15, a sacrificial material 471 may then be formed for filling each of the first gate recesses 427 and each of the second gate recesses 428. Subsequently, a photo resist layer 472 may be used to perform an etching process for forming a diffusion contact hole 491 and a diffusion contact hole 492. It is worth noticing that the diffusion contact hole 491 may only expose the diffusion region 412, and the diffusion contact hole 492 may partially expose the diffusion region 412 and partially expose the sacrificial material 471 in the second gate recess 428. As shown in FIG. 16, the photo resist layer 472 and the sacrificial layer 471 may then be removed for forming a semiconductor device 401. The semiconductor device 401 in this embodiment is a kind of a semi-finished product, and other work function metal layers and main conductive layers may be selectively formed in the diffusion contact hole 491 and the diffusion contact hole 492 for forming diffusion contact plugs and metal gate structures. The diffusion contact plug and the metal gate structure in the diffusion contact hole 492 are formed simultaneously and are electrically connected to each other, and the semiconductor device 401 in this embodiment may therefore be employed for forming an SRAM, but not limited thereto.

It is worth noticing that the “gate-last for high-k first” process is performed in all the embodiments mentioned above, and the high-k gate dielectric layer has a “-”-shaped profile structure, but the high-k gate dielectric layer in the present invention is not limited to this and may have a U-shaped profile structure when the high-k last process is performed in other embodiments of the present invention.

To summarize the above descriptions, in the manufacturing method of the semiconductor device of the present invention, the diffusion contact holes are formed before completing the replacement metal gate process, and the metal gate structure may avoid being damaged during forming the diffusion contact holes. The process window and the process limitation of the etching process for forming the diffusion contact holes may accordingly improved, and the process yield and the device quality may also be enhanced.

Those skilled in the art will readily observe that numerous modifications and alterations of the device and method may be made while retaining the teachings of the invention. Accordingly, the above disclosure should be construed as limited only by the metes and bounds of the appended claims.

1. A manufacturing method of a semiconductor device, comprising:
providing a substrate having at least a sacrificial gate structure formed thereon, at least a diffusion region formed therein at two sides of the sacrificial gate structure, and a first inter-layer dielectric (ILD) layer formed thereon for covering the diffusion region;
forming a gate recess in the sacrificial gate structure;
forming a first diffusion contact hole in the first ILD layer for at least partially exposing the diffusion region; and
forming a metal layer in both the gate recess and the first diffusion contact hole.

2. The manufacturing method of the semiconductor device of claim 1, wherein the metal layer comprises a work function metal layer and a main conductive layer.

3. The manufacturing method of the semiconductor device of claim 2, further comprising:
performing a planarization process for removing a part of the work function metal layer and a part of the main conductive layer;
forming a second ILD layer covering the substrate and the main conductive layer, and
forming a gate contact hole and a second diffusion contact hole in the second ILD layer, wherein the gate contact hole at least partially exposes the main conductive layer in the gate recess, and the second diffusion contact hole at least partially exposes the main conductive layer in the first diffusion contact hole.

4. The manufacturing method of the semiconductor device of claim 2, further comprising performing an etching process for removing a part of the work function metal layer in the gate recess before forming the main conductive layer.

5. The manufacturing method of the semiconductor device of claim 1, wherein a high dielectric constant (high-k) gate dielectric layer and a gate sacrificial material layer are formed in the gate sacrificial structure, and the high-k gate dielectric layer is formed between the substrate and the gate sacrificial material layer.

6. A manufacturing method of a semiconductor device, comprising:
providing a substrate having at least a first semiconductor unit, at least a second semiconductor unit and a first ILD layer formed thereon, wherein the first semiconductor unit has a first sacrificial gate structure formed therein and at least a first diffusion region formed in the substrate at two sides of the first sacrificial gate structure, the second semiconductor unit has a second sacrificial gate structure formed therein and at least a second diffusion region formed in the substrate at two sides of the second sacrificial gate structure, and the first ILD layer is formed for covering the first diffusion region and the second diffusion region;
forming a first gate recess in the first sacrificial gate structure;
forming a second gate recess in the second sacrificial gate structure;
forming a plurality of first diffusion contact holes in the first ILD layer for at least partially exposing the first diffusion region or the second diffusion region; and
forming a metal layer in the first gate recess, the second gate recess, and the first diffusion contact hole.

7. The manufacturing method of the semiconductor device of claim 6, wherein the metal layer comprises a first work function metal layer and a main conductive layer.

8. The manufacturing method of the semiconductor device of claim 6, further comprising forming a second work function metal layer in the second gate recess before forming the first work function metal layer.

9. The manufacturing method of the semiconductor device of claim 7, further comprising:
performing a planarization process for removing a part of the first work function metal layer and a part of the main conductive layer;
forming a second ILD layer covering the substrate and the main conductive layer, and
forming a plurality of gate contact holes and a plurality of second diffusion contact holes in the second ILD layer, wherein each of the gate contact holes at least partially exposes the main conductive layer in the first gate recess or the main conductive layer in the second gate recess, and the each of the second diffusion contacts hole at least partially exposes the main conductive layer in the first diffusion contact hole.

10. The manufacturing method of the semiconductor device of claim 8, further comprising performing an etching process for removing a part of the first work function metal layer and a part of the second work function metal layer.

11. The manufacturing method of the semiconductor device of claim 6, wherein a high-k gate dielectric layer and a gate sacrificial material layer are formed in the first gate sacrificial structure and the second gate sacrificial structure, and the high-k gate dielectric layer is formed between the substrate and the gate sacrificial material layer.

12. The manufacturing method of the semiconductor device of claim 6, wherein a conductive type of the first semiconductor is an n-type and a conductive type of the second semiconductor is a p-type.

13. The manufacturing method of the semiconductor device of claim 6, further comprising:
forming a sacrificial material for filling the first gate recess and the second gate recess; and
removing the sacrificial material after forming the first diffusion contact holes;
wherein at least a part of the first diffusion contact holes partially expose the sacrificial material.

14. A semiconductor device, comprising:
a substrate;
a high-k gate dielectric layer disposed on the substrate;
a metal gate structure disposed on the high-k gate dielectric layer;
a diffusion region disposed in the substrate at two sides of the metal gate structure;
a first ILD layer disposed on the diffusion region, wherein the first ILD layer has a first diffusion contact hole at least partially exposing the diffusion region; and
a diffusion contact plug disposed in the first diffusion contact hole, wherein both the diffusion contact plug and the metal gate structure comprise a work function layer and a main conductive layer.

15. The semiconductor device of claim 14, further comprising a second ILD layer disposed on the metal gate structure and the diffusion contact plug, the second ILD layer comprising a gate contact plug and a second diffusion contact plug, wherein the gate contact plug is electrically connected to the metal gate structure, and the second diffusion contact is electrically connected to the diffusion contact plug.

16. A semiconductor device, comprising:
a substrate;
a first semiconductor unit and a second semiconductor unit disposed on the substrate, wherein the first semiconductor unit comprises a first metal gate structure and at least a first diffusion region disposed in the substrate at two sides of the first metal gate structure, and the second semiconductor unit comprises a second metal gate structure and at least a second diffusion region disposed in the substrate at two sides of the second metal gate structure;
a first ILD layer disposed on the first diffusion region and the second diffusion region, wherein the first ILD layer has a plurality of first diffusion contact holes at least partially exposing the first diffusion region or the second diffusion region; and
a plurality of diffusion contact plugs respectively disposed in each of the first diffusion contact holes, wherein the diffusion contact plugs, the first metal gate structure and the second metal gate structure comprise a first work function layer and a main conductive layer.

17. The semiconductor device of claim 16, wherein the second metal gate structure further comprises a second work function metal layer disposed between the first work function metal layer and the substrate.

18. The semiconductor device of claim 16, further comprising a second ILD layer disposed on the first metal gate structure, the second metal gate structure and the diffusion contact plugs, the second ILD layer comprising a plurality of gate contact plugs and a plurality of second diffusion contact plugs, wherein each of the gate contact plugs is electrically connected to the first metal gate structure or the second metal gate structure, and each of the second diffusion contact plugs is electrically connected to the diffusion contact plug.

19. The semiconductor device of claim 16, wherein a conductive type of the first semiconductor unit is an n-type and a conductive type of the second semiconductor unit is a p-type.

20. The semiconductor device of claim 16, wherein both the first semiconductor unit and the second semiconductor unit comprise a high-k gate dielectric layer.
